(19) United States
(12) Patent Application Publication
(10) Pub. No.: US 2008/0293253 A1
(43) Pub. Date: Nov. 27, 2008

(54) Wet etching of the edge and bevel of a silicon wafer

(76) Inventor: Herman Itzkowitz, Bala Cynwyd, PA (US)

Correspondence Address: JOHN W. GOLDSCHMIDT, JR. ESQUIRE;DILWORTH PAXON LLP, 3200 MELLON BANK CENTER, 1735 MARKET STREET, PHILADELPHIA, PA, 19103, US

(21) Appl. No.: 12/214,446

(22) Filed: Jun. 18, 2008

Related U.S. Application Data
(63) Continuation-in-part of application No. 11/294,644, filed on Dec. 5, 2005.
(60) Provisional application No. 60/633,061, filed on Dec. 3, 2004.
(60) Provisional application No. 60/936,216, filed on Jun. 18, 2007.

(51) Int. Cl. H01L 21/306

(52) U.S. Cl. 438/745; 156/345.23; 257/E21.219

(57) ABSTRACT

An apparatus and method used to selectively etch materials from the edge and bevel areas of a silicon wafer are provided. In one configuration, a bevel etch spin chuck, for use in a device for removing unwanted material from an edge and bevel area of a wafer, includes a fluid channel, a separation barrier, and a gas channel that are substantially circular and concentric. A fluid, such as an etching solution, is provided to the fluid channel and contacts one or more areas at the edge and bevel area of the wafer. A stream of continuously flowing gas, such as nitrogen, is provided to the gas channel and purges an active side of the wafer.

### CROSS REFERENCE TO RELATED APPLICATIONS

This application is a continuation-in-part of U.S. patent application Ser. No. 11/294,644, filed Dec. 5, 2005, which claims priority to U.S. provisional patent application Ser. No. 60/633,061, filed Dec. 3, 2004. This application also claims priority to U.S. provisional patent application Ser. No. 60/936,216, filed Jun. 18, 2007. These three related patent applications in their entirety are hereby incorporated by reference into this application.

### FIELD OF THE INVENTION

This invention generally relates to the manufacture of devices employing wet etching processes. More specifically, this invention relates to a method and apparatus for removing and reducing contaminants present in, or introduced during, the wet etching process, wherein the devices produced by such processes are produced without a substantial decrease in performance of the resulting device.

### BACKGROUND OF THE INVENTION

The continued decrease in the sizes of devices being produced from silicon or other substrate wafers in wet etching processes has made the wafers more vulnerable to contamination from particles and debris. Semiconductor manufactures utilize a number of cleaning procedures throughout the process of wafer manufacture to remove undesirable debris from the wafer surface.

Loss analysis studies have indicated that a significant source of debris that leads to a reduction in wafer yield is the presence of undesirable substances on the wafer backside and on the outer several millimeters of the feature, active or top side or surface of the wafer. These debris may comprise both contamination from foreign particles and desired and/or undesired materials and/or layers which are present in, or introduced during, the wafer manufacturing process. In one instance, desired materials may be deposited or collected at or near this edge of the wafer without the benefit of tight control due to the location at the edge of the wafer. An etching process that removes all materials on the wafer backside and on the feature side along the edge of the wafer without adversely impacting the ultimate performance of the devices being produced will generally remove the source of contamination, and thus increase wafer yield.

These materials may be removed from the backside and outer feature side edges through the application of a barrier layer, followed by a thin layer of copper applied by a physical vapor deposition (PVD) process, followed by a thicker layer of copper using electroplating. However, poor quality at the edge of the wafer may result in the thin layer of copper flaking off causing contamination in subsequent steps of the etching process, or diffusing into the silicon or substrate material due to problems with the barrier layer of the substrate. Thus, the need exists for a process and apparatus to enable excess copper, and other undesirable deposits on the surface of the wafer, to be removed during the etching process.

### SUMMARY OF THE INVENTION

This problem may be solved by etching away the copper layer, or other undesirable contaminants, at the edge of the wafer to a distance where all the layers being deposited on the surface of the wafer are applied to the wafer properly without adversely impacting the performance of the device produced by the etching process.

Layers that often need to be removed from the edge or other areas of the wafer are: copper, aluminum, silicon-oxide and silicon-nitrite, although it may be desirable to remove other materials from the wafer. The distance from the edge should be precisely controlled to insure that the defective areas are substantially completely removed and that there is no substantial undesired etching in the active areas of the device produced from the wafer being etched.

In one embodiment of this invention, a bevel etch spin chuck, for use in a device for removing unwanted material from an edge and bevel area of a wafer, comprises means for providing a cushion of continuously flowing gas sufficient to support a wafer placed on the chuck; a plurality of retaining pins disposed in a substantially circular pattern to center the wafer on the chuck; a substantially circular fluid channel that is substantially concentric to the pattern of the retaining pins; a substantially circular gas channel that is substantially concentric to the fluid channel; and a substantially circular separation barrier that is substantially concentric to the fluid channel and disposed between the fluid channel and the gas channel, wherein a fluid provided to the fluid channel contacts one or more areas at the edge and bevel area of the wafer, and a stream of continuously flowing gas provided to the gas channel purges an active side of the wafer.

In another embodiment, the bevel edge spin chuck of further comprises: first supply means for supplying the fluid; and a first lower channel connected to the fluid channel adapted to direct the fluid from the first supply means to the fluid channel by centrifugal force when the wafer is spinning on the chuck.

In another embodiment, the means for supplying the fluid includes a nozzle pointed toward the first lower channel.

In another embodiment of the invention, a method for removing unwanted material from edge and bevel areas of a wafer having a feature and non-feature surfaces, comprises: placing the wafer, feature-side down, on a cushion of continuously flowing gas sufficient to support the wafer on a bevel edge spin chuck, wherein the chuck comprises a plurality of retaining pins disposed in a substantially circular pattern to center the wafer on the chuck a substantially circular fluid channel that is substantially concentric to the pattern of the retaining pins, a substantially circular gas channel that is substantially concentric to the fluid channel, and a substantially circular separation barrier that is substantially concentric to the fluid channel and disposed between the fluid channel and the gas channel; rotating the chuck and supported wafer at a rate that creates a centrifugal force that carries a fluid to the fluid channel; and providing a stream of continuously flowing gas to the gas channel, wherein the fluid contacts one or more areas at the edge and bevel area of the wafer, and the stream of continuously flowing gas purges the feature side of the wafer.

### BRIEF DESCRIPTION OF THE DRAWINGS

Understanding of the present invention will be facilitated by consideration of the following detailed description of the embodiments of the present invention taken in conjunction with the accompanying drawings, in which like numerals refer to like parts, and wherein:

FIG. 1 shows a plan view of the active side of a wafer produced by this invention.

FIG. 2 is a perspective view of one embodiment of a bevel etch spin chuck of this invention.

FIG. 3A is a cross section of the bevel etch spin chuck of FIG. 2, taken through the fluid path.

FIG. 3B is a cross section of the bevel etch spin chuck of FIG. 2, taken through the gas path.

FIG. 4 depicts a cross sectional view of the wafer of FIG. 1, and an exploded view of the edge of the wafer of FIG. 4.

FIG. 5 is a cross section of another embodiment of the bevel etch spin chuck of this invention.

FIG. 6 shows a cross sectional detail of the spin chuck of FIG. 5.

### DETAILED DESCRIPTION OF PREFERRED EMBODIMENTS

It is to be understood that the figures and descriptions of the present invention have been simplified to illustrate elements that are relevant for a clear understanding of the present invention, while eliminating, for the purposes of clarity, many other elements which may be found in the present invention. Those of ordinary skill in the pertinent art will recognize that other elements are desirable and/or required in order to implement the present invention. However, because such elements are well known in the art, and because such elements do not facilitate a better understanding of the present invention, a discussion of such elements is not provided herein.

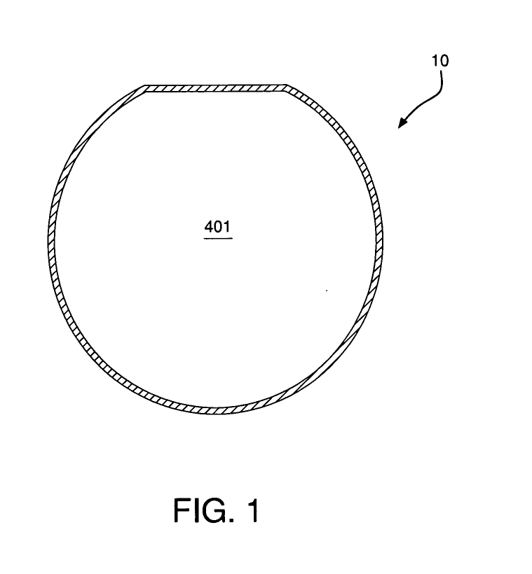

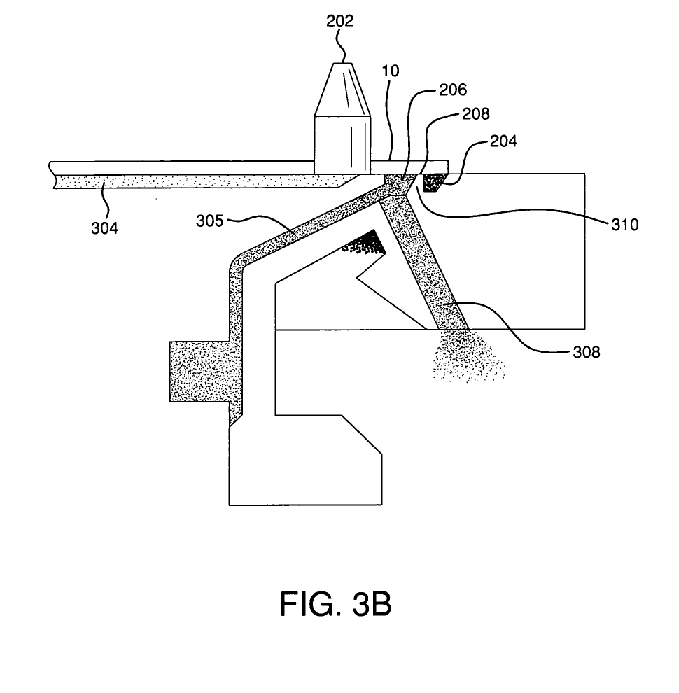

Turning now to FIGS. 1 and 4, FIG. 1 shows a plan view of active side 401 of wafer 10, which during at least one embodiment of the bevel etching process of this invention is facing downward. Numeral 401 depicts active protected area of wafer 10 which is not etched. Referring now to FIG. 4, areas 402, 403 (comprising areas 403a, 403b, and 403c), and 404 are the areas where etching takes place, while area 401 is the active feature area of wafer 10 which is not etched.

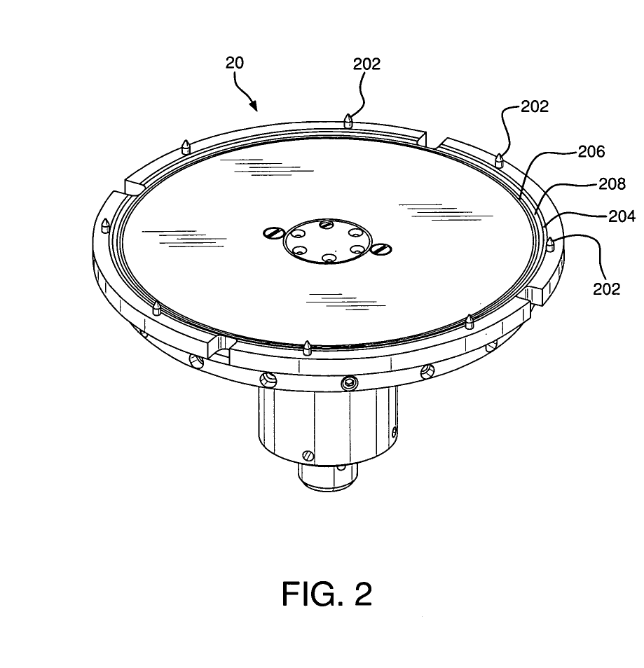

FIG. 2 depicts a bevel edge spin chuck 20 in accordance with one embodiment of the invention, showing retaining pins 202, fluid channel 204, gas channel 206, and separation barrier 208. In preferred embodiments, a fluid such as an etching solution is provided to fluid channel 204 and an inert gas such as nitrogen is provided to gas channel 206.

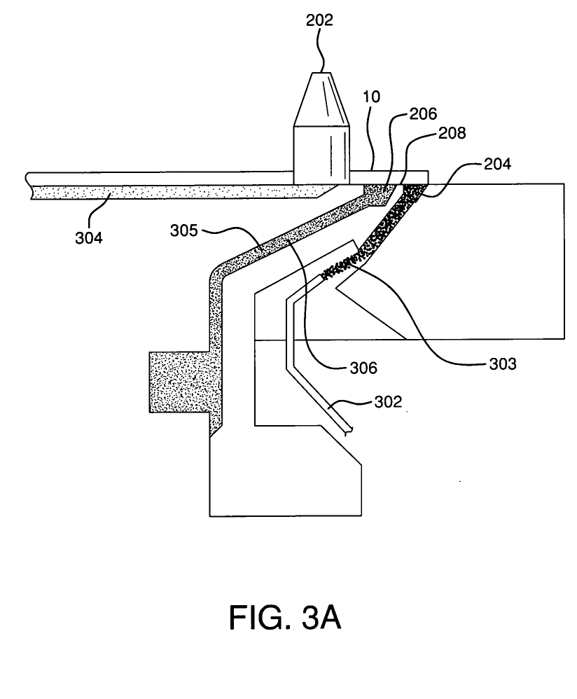

FIG. 3A is a cross section of chuck 20 taken along a path leading to fluid channel 204. A wafer 10 is placed on the chuck with the active surface facing down onto a cushion of inert gas 304. Preferably, inert gas 304 is nitrogen, provided in a conventional manner from a source (not shown) at a relatively low flow rate. Retaining pins 202 are used to center the wafer and prevent it from floating sideways off the chuck.

In a preferred embodiment, stream nozzle 302 delivers an etching solution below the wafer into lower channel 303 in chuck 20 while the chuck is rotating. Preferably, stream nozzle 302 is stationary and pointed toward lower channel 303. Centrifugal force carries the etching solution to fluid channel 204, where the solution contacts the edge of the wafer. Excess fluid flows out radially away from the wafer.

Preferably, fluid channel 204 delivers etching solution so that a portion of area 402 (up to separation barrier 208) and areas 403a and 403b are affected, while areas 403c and 404 are not. The placement and size of separation barrier 208 determine the portion of area 402 that is affected by the etching solution in fluid channel 204. Those skilled in the art will recognize that other embodiments of the invention may be used so that the etching solution affects either or both of area 403c and a portion of area 404.

In this embodiment, an inert gas 305 is provided to lower channel 306 in chuck 10 while the chuck is rotating. Preferably, inert gas 305 is also nitrogen, provided in a conventional manner at a relatively high flow rate and in relatively high volume so that it flows through lower channel 306 to gas channel 206. In this way, inert gas 305 is used to purge the active side 401 of wafer 10 to ensure that vapors from the etching solution do not affect active side 401.

FIG. 3B is a cross section of chuck 20, slightly rotated from the cross section of FIG. 3A, taken along a path leading to gas channel 206. A high volume of inert gas 304 is introduced at the edge of wafer 10, inward from the area to be etched by the etching solution in fluid channel 206. Inert gas 304 is allowed to escape toward the bottom of chuck 20 through gas openings 308. (Although only one gas opening 308 is depicted in FIG. 3B, preferably a number of gas openings 308 are provided at intervals around chuck 20.) By maintaining, in a conventional manner, a slightly positive pressure in air channel 310 next to separation barrier 208, fumes from the etching solution flowing to fluid channel 204 are prevented from migrating to active side 401 of wafer 10.

In another embodiment, this invention generally comprises a method and apparatus for removing unwanted material from the edge and bevel areas of a wafer, by: placing the wafer (having a feature side and non-feature side), feature-side down on a cushion of gas above a spin chuck, wherein the chuck has a bevel flow ring; vertically setting the size of the flow ring; rotating the spin chuck and supported wafer at a rate in order to create a centrifugal force affecting any fluid applied to the wafer; and applying a chemical etching fluid to the non-feature-side of the wafer, in amount sufficient to fill a gap between the wafer and the flow ring as the etching fluid flows over the edge of the wafer onto the flow ring, and into a space between the wafer and the flow ring, wherein the feature side of the wafer is substantially protected from exposure to the etching fluid and the areas etched are determined by an overlap between the wafer and the ring.

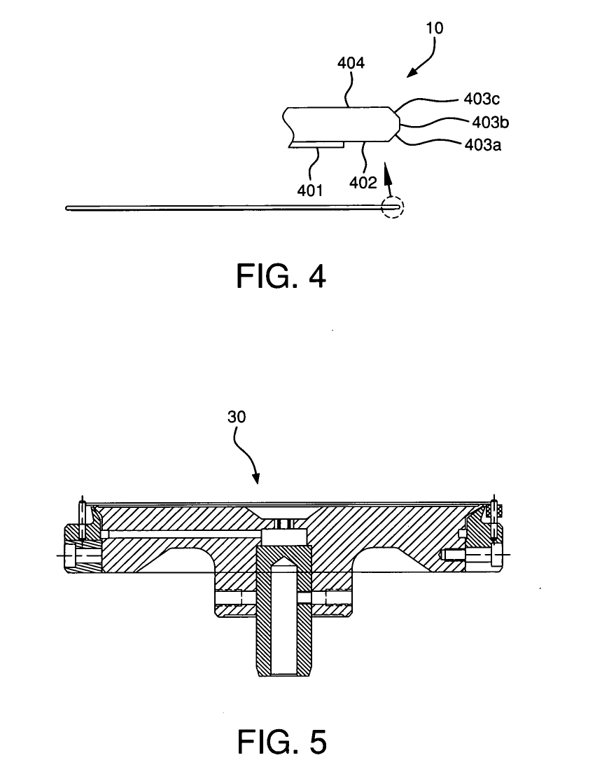

FIG. 5 depicts the cross section of a bevel etch spin chuck 30 in accordance with another embodiment of this invention. Chemical etching fluid is dispensed above wafer 10 and as spin chuck 30 rotates, the etching fluid flows to the outside periphery or edge of wafer 10.

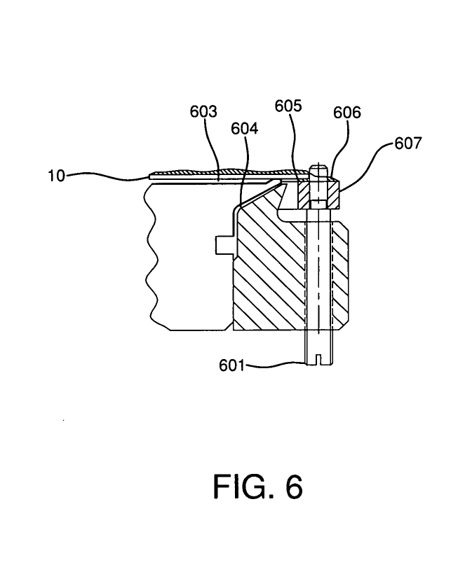

FIG. 6 shows a detail of the cross section of spin chuck 30 of FIG. 2. Wafer 10 is placed on chuck 30 with the active area 401 facing down and protected by a continuous flow of nitrogen or other gas 603 which creates a cushion between wafer 10 and the chuck 30. The gas is fed through channel 604 to create gas cushion 603. An outside ring 607 can be adjusted in the vertical orientation by adjusting screw 601. The adjustment is made so there is a gap 605 between ring 607 and active area 401 of wafer 10. The fluid dispensed above wafer 10 fills gap 605, with the excess overflowing into area 606.

Wafer 10 is processed feature side 401 down on a rotating chuck 30. Wafer 10 floats on nitrogen or other gas cushion 603 that prevents contact with chuck 30 and prevents chemical etching fluid or other chemistry from reaching active area 401 of wafer 10. Chuck 30 contains bevel flow ring 607 that can be set to a fixed gap 605 between flow ring 607 and wafer 10. Chemical etching fluid or other chemistry is dispensed from above on the backside or non-active area 404 of wafer 10. Due to the centrifugal force, the chemistry flows to the outer edge of wafer 10. The chemistry then flows off wafer 10 edge and down onto flow ring 607. The chemistry fills bevel flow ring 607 and contacts the outer edge (typically by about several millimeters) on feature side 401 of wafer 10. With a relatively slow rotational velocity (typically between about 50 rpm and about 1200 rpm), chemistry is held by surface tension in gap 605 between wafer 10 and flow ring 607. The etch distance from the edge of wafer 10 is determined by the distance that flow ring 607 overlaps with wafer 10. The fluid in gap 605 also acts as a seal and prevents fluid from splashing onto active area 401 of wafer 10.

Once the etching process is complete, the rotational velocity is increased (typically from between about 500 rpm to about 2000 rpm) to force the chemistry out of gap 605.

If multiple layers are present, several chemistries may be required to etch down to the desired surfaces of wafer 10. When the etching process is complete, wafer 10 may be rinsed and spun dry.

In the instant embodiment, gap 605 varies between about 0.001″ and about 0.015″ depending on the viscosity and surface tension of the etching fluid. Also in this embodiment, wafer 10 and flow ring 607 may overlap by about 0.5 to about 5 mm which determines the distance from the edge of the etched area of wafer 10.

Another embodiment of the invention concerns backside and bevel edge cleaning. Bevel etch control for 300 mm wafers allows oxide, nitride, poly silicon, and copper removal from backside and bevel exclusion zone. Proprietary spindle tooling enables specific bevel and side edge etching, independent of the wafer backside using a simple, mechanically determined etching area. This capability includes programmable flow rate for the bevel etch and the ability for DI rinse of the bevel area. The process can be used for all wafer sizes, including notched and flat wafers, with bevel 0.8-5 mm.

The disclosure herein is directed to certain features of the elements and methods of the invention disclosed as well as others that will be apparent to those skilled in the art in light of the disclosure herein. Thus, it is intended that the present invention covers all such modifications and variations of this invention, provided that those modifications come within the scope of the claims granted herein and the equivalents thereof.

What is claimed is:

1. A bevel etch spin chuck, for use in a device for removing unwanted material from an edge and bevel area of a wafer, comprising:
(a) means for providing a cushion of continuously flowing gas sufficient to support a wafer placed on the chuck;
(b) a plurality of retaining pins disposed in a substantially circular pattern to center the wafer on the chuck;
(c) a substantially circular fluid channel that is substantially concentric to the pattern of the retaining pins;
(d) a substantially circular gas channel that is substantially concentric to the fluid channel; and
(e) a substantially circular separation barrier that is substantially concentric to the fluid channel and disposed between the fluid channel and the gas channel,
(f) wherein a fluid provided to the fluid channel contacts one or more areas at the edge and bevel area of the wafer, and a stream of continuously flowing gas provided to the gas channel purges an active side of the wafer.

2. The bevel edge spin chuck of claim 1, further comprising:
(a) first supply means for supplying the fluid; and
(b) a first lower channel connected to the fluid channel adapted to direct the fluid from the first supply means to the fluid channel by centrifugal force when the wafer is spinning on the chuck.

3. The bevel edge spin chuck of claim 2, wherein the means for supplying the fluid includes a nozzle pointed toward the first lower channel.

4. The bevel edge spin chuck of claim 1, further comprising:
(a) second supply means for supplying the stream of continuously flowing gas; and
(b) a second lower channel connected to the gas channel adapted to direct the stream of continuously flowing gas from the second supply means to the gas channel.

5. The bevel edge spin chuck of claim 1, wherein the cushion of continuously flowing gas and the stream of continuously flowing gas are nitrogen.

6. The bevel edge spin chuck of claim 1, wherein the fluid is an etching solution.

7. The bevel edge spin chuck of claim 1, wherein the cushion of continuously flowing gas flows at a relatively low flow rate, and the stream of continuously flowing gas flows at a relatively high rate.

8. A method for removing unwanted material from edge and bevel areas of a wafer having a feature and non-feature surfaces, comprising:
(a) placing the wafer, feature-side down, on a cushion of continuously flowing gas sufficient to support the wafer on a bevel edge spin chuck, wherein the chuck comprises:
(i) a plurality of retaining pins disposed in a substantially circular pattern to center the wafer on the chuck;
(ii) a substantially circular fluid channel that is substantially concentric to the pattern of the retaining pins;
(iii) a substantially circular gas channel that is substantially concentric to the fluid channel; and
(iv) a substantially circular separation barrier that is substantially concentric to the fluid channel and disposed between the fluid channel and the gas channel;
(b) rotating the chuck and supported wafer at a rate that creates a centrifugal force that carries a fluid to the fluid channel; and
(c) providing a stream of continuously flowing gas to the gas channel,
(d) wherein the fluid contacts one or more areas at the edge and bevel area of the wafer, and the stream of continuously flowing gas purges the feature side of the wafer.

9. The method of claim 8, wherein the cushion of continuously flowing gas and the stream of continuously flowing gas are nitrogen.

10. The method of claim 8, wherein the fluid is an etching solution.

11. The method of claim 8, wherein the cushion of continuously flowing gas flows at a relatively low flow rate, and the stream of continuously flowing gas flows at a relatively high rate.
